(19) United States
(12) Patent Application Publication
(10) Pub. No.: US 2003/0211427 A1
(43) Pub. Date: Nov. 13, 2003

(54) Method and apparatus for thick film photoresist stripping

(75) Inventors: Wen-Hsiang Tseng, Hsin-Chu (TW); Tung-Wen Hsieh, Maidi (TW); Yu-Hsi Wang, Taichung (TW); Wei-Jen Huang, Hsin-Chu (TW); Sheng-Liang Pan, Hsin-Chu City (TW); Szu-Yao Wang, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/140,740

(22) Filed: May 7, 2002

(51) Int. Cl. G03F 7/30; C23G 1/00; B08B 3/00; C03C 23/00

(52) U.S. Cl. 430/329; 134/2; 134/147

(57) ABSTRACT

The present invention provides a method for avoiding particulate contamination of a semiconductor wafer in a stripping bath and a stripping system for implementing the method. The method includes providing at least one semiconductor wafer vertically oriented in a wafer containing fixture; providing a solution bath for removing particulate material from a semiconductor wafer surface; immersing the wafer containing fixture in the solution bath positioned over a movable member having a contact surface such that upon moving the movable member in a vertical direction the contact surface contacts a portion of the edge of the at least one semiconductor; and moving the movable member such that the at least one semiconductor wafer is projected upward from a resting position in the wafer containing fixture.

### FIELD OF THE INVENTION

This invention generally relates to thick film photoresist stripping and more particularly to a method and apparatus to prevent contamination of a semiconductor wafer from photoresist flakes in a stripping process.

### BACKGROUND OF THE INVENTION

Packaging of the ULSI chip is one of the most important steps in ULSI manufacturing, contributing significantly to the overall cost, performance and reliability of the packaged chip. As semiconductor devices reach higher levels of integration, packaging technologies such as chip bonding have become critical. Packaging of the chip accounts for a considerable portion of the cost of producing the device and failure of the package leads to costly yield reduction.

Some chip bonding technologies utilize a solder bump attached to a contact pad (chip bond pad) on the chip to make an electrical connection from the chip devices to the package. Another chip bonding technology where a reworking process may be advantageously used is a ball-grid array (BGA) package where solder (e.g., Pb/Sn) bumps are placed on the package surface and chip bond pads are bonded to the package by means of the package solder bump. Solder bumps maybe formed by, for example, vapor deposition of solder material over layers of under bump metallization (UBM) formed over the chip bonding pad. In another method, the layers of solder material may deposited by electrodeposition onto a seed layer material deposited over layers of under bump metallization (UBM) formed on the chip bonding pad. In yet another method, solder bumps may be formed by a solder-paste screen printing method using a mask (stencil) to guide the placement of the solder-paste. Typically, after deposition of the solder materials, for example, in layers or as a homogeneous mixture, the solder bump (ball) is formed by heating the solder material to a melting point where according to a reflow process a solder ball is formed with the aid of surface tension. Alternatively, a solder bump (column) may be formed within a permanent mask made of photoresist or some other organic resinous material defining the solder bump area over the chip bonding pad.

In order to define the area over which solder material will be applied, such as the chip bonding pad, a thick film of photoresist also referred to a dry film resist (DFR) is used pattern and define an area for depositing the solder material, for example by electroplating or screen printing. In a typical processing scheme, a photoresist composition is spun on or applied to the substrate with different methods known in the art. The photoresist composition may be subjected to a pre-exposure bake to drive off a proportion of the solvent and impart dimensional stability to the film. The coated substrate is then exposed to activating light radiation through a mask to define a pattern on the photoresist surface. Following exposure, the photoresist is developed, for example, by a wet etching process where selected portions of the patterned photoresist are removed according to selective dissolution of portions of the patterned photoresist to create, for example, pattern of openings for solder column formation. Following a solder column formation step, for example, depositing solder material within the openings in the patterned photoresist, it is necessary to strip (remove) the remaining photoresist for carrying out subsequent processing steps, for example, completing the formation of solder bumps.

It is highly important to completely remove developed portions of the photoresist pattern in the wet etching process to avoid problems with subsequent processing steps. Incomplete removal of photoresist according to a developing procedure or a stripping procedure will lead to subsequent processing defects including improperly formed solder bumps and improperly plasma etched surfaces over the bonding pad.

In an exemplary process for forming a solder bump on a semiconductor chip, reference is made to FIGS. 1A-1E representational of cross sections of exemplary stages in a manufacturing process for forming a solder bump for chip bonding in flip chip technology. For example, with reference to FIG. 1A, the process of creating the solder bumps begins after chip bonding pad 10, for example Cu or Al, formed by vapor deposition has been deposited on the surface of the semiconductor wafer 8.

After the chip bonding pad 10 is formed, a passivation layer 12 of, for example, silicon dioxide (SiO₂) is formed over the semiconductor device surface excluding a portion overlying the chip bonding pad 10. Typically, one or more under bump metallization (UBM) layers, e.g., 14A of from about 500 Angstroms to about 5000 Angstroms are then deposited over chip bonding pad 10 and a layer of dry film photoresist 16 is formed thereover as shown in FIG. 1B. The UBM layer 14A may be, for example, a layer of titanium. The photoresist layer is typically about 100 to 150 microns high. As shown in FIG. 1B, the photoresist layer 16 is photolithographically patterned and developed to form an opening 17 above the contact pad 10 to expose the UBM layer, e.g., 14A.

Additional UBM layers may be formed within the mask opening 17 by, for example, an electroplating process or vapor deposition process forming e.g., UBM layers 14B and 14C shown in FIG. 1C. Layers 14B and 14C may be for example, layers of copper and nickel, respectively. UBM layers are formed over the chip bonding pad 10, for example, to allow for better bonding and wetting of the solder material to the uppermost UBM layer adjacent the solder material, e.g., 14C, and for protection of the chip bonding pad 10 by the lowermost UBM layer, e.g., 14A. A column of solder material 18A may either be deposited in layers, for example, a layer of Pb followed by a layer of Sn, the solder material layers later being formed into a homogeneous solder during reflow, or may be deposited as a homogeneous solder material by for example vapor deposition or electroplating onto a seed layer (e.g., 14C).

In a typical approach to forming a solder bump the photoresist layer 16 is first removed (stripped) according to a wet etching process. The exposed the UBM layer 14A is then dry etched through by a reactive ion etch (RIE) process to the underlying passivation layer 12 using the solder column 18A as an etching mask to protect the underlying UBM layers e.g., 14A, 14B, and 14C, as shown in FIG. 1D. The solder column 18 is then heated to reflow to form a solder bump 18B over the UBM layer 14C as shown in FIG. 1E. After reflow, a homogeneous Pb/Sn solder bump with a well defined melting temperature.

One problem with the prior art method of solder bump formation is the method for stripping (wet etching) the thick dry film photoresist used in the process. Typically, several semiconductor wafers are loaded into a cassette and immersed in a stripping bath including a stripping solution and some form of agitation, for example, ultrasound or gas bubbles. The stripping solution, including for example hydroxide and N-methyl-2-pyrrolidone (NMP), is used for removing the thick film photoresist. In operation, the solvent solution penetrates into the thick film photoresist causing it to swell whereby relatively large pieces or flakes of the photoresist are removed without completely dissolving in the solution. Dry, thick film photoresist is typically a durable and highly cross-linked polymer for example, resistant to salvation by conventional strippers. As a result, flakes of undissolved photoresist remain in the stripping solution and frequently redepositing on the semiconductor wafer.

For example, referring to FIG. 2A is shown a head on view of a portion of a cassette wafer holding fixture 22 holding a semiconductor wafer 24 viewed head-on with respect to the wafer. The wafer is typically held in place by slots (not shown) formed in the side of the cassette. During the stripping process, the pieces of photoresist which have been broken off by the selective dissolution action of the stripping solution tend to accumulate at the lower portion of the cassette, for example, in areas along angled portions 26A and 26B of the cassette fixture 22. In practice, the photoresist flakes tends to redeposit on the semiconductor wafer along the circumference along the lower portion of the cassette where it accumulates during the stripping process. As a result, the semiconductor wafer including a circumferential portion contacting angled portions 26A and 26B is contaminated by adhering flakes of photoresist thereby adversely affecting downstream processes leading to a reduced yield of semiconductor devices.

These and other shortcomings demonstrate a need in the semiconductor processing art to develop a method and apparatus for reducing or avoiding the contamination of semiconductor wafers during a photoresist stripping process.

It is therefore an object of the invention to provide a method and apparatus for reducing or avoiding the contamination of semiconductor wafers during a photoresist stripping process while overcoming other shortcomings and deficiencies in the prior art.

### SUMMARY OF THE INVENTION

To achieve the foregoing and other objects, and in accordance with the purposes of the present invention, as embodied and broadly described herein, the present invention provides a method for avoiding particulate contamination of a semiconductor wafer in a stripping bath and a stripping system for implementing the method.

In a first embodiment, the method includes providing at least one semiconductor wafer vertically oriented in a wafer containing fixture; providing a solution bath for removing particulate material from a semiconductor wafer surface; immersing the wafer containing fixture in the solution bath positioned over a movable member having a contact surface such that upon moving the movable member in a vertical direction the contact surface contacts a portion of the edge of the at least one semiconductor; and, moving the movable member such that the at least one semiconductor wafer is projected upward from a resting position in the wafer containing fixture.

In another embodiment, the stripping system includes a stripping solution container for holding a stripping solution and for containing a plurality of semiconductor wafers vertically oriented in a wafer cassette holder the stripping solution container including an elongated rotatable member positioned in the lower portion of the stripping solution container such that upon positioning the wafer cassette holder over at least an axial portion of the elongated rotatable member at least a radial portion of the elongated rotatable member periphery contacts the plurality of semiconductors at an edge at least upon rotation about an axial direction of the elongated rotatable member to project the plurality of semiconductors in an upward direction from a resting position in the wafer cassette holder.

These and other embodiments, aspects and features of the invention will be better understood from a detailed description of the preferred embodiments of the invention which are further described below in conjunction with the accompanying Figures.

### BRIEF DESCRIPTION OF THE DRAWINGS

FIGS. 1A-1E are cross sectional side views of different stages in a solder bump formation process including thick film photoresist removal according to the prior art.

FIG. 2A is a head-on representational view of a portion of wafer holding cassette and semiconductor wafer according to a stripping method of the prior art.

FIGS. 3A-3C are views along a rotational axis of representational exemplary embodiments of movable members according to the present invention.

FIGS. 4A and 4B are exemplary embodiments of the stripping system according to the present invention.

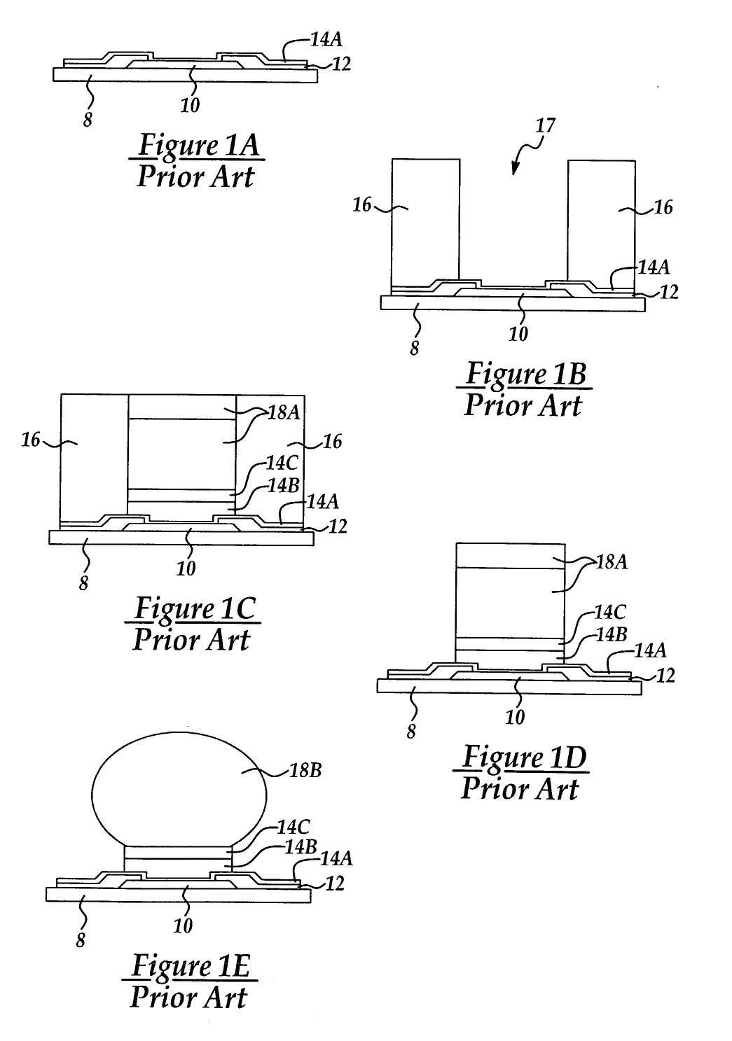

### DETAILED DESCRIPTION OF THE PREFERRED EMBODIMENTS

While the method and apparatus of the present invention are explained with reference to the use of a dry, thick film photoresist in a solder bump formation process, it will be appreciated that the method and apparatus of the present invention may be advantageously applied to any wet etching or stripping process where it would be advantageous to reduce contamination of a substrate by undissolved particles in a cleaning or stripping solution.

In one embodiment of the present invention, an movable member is positioned below at least one vertically oriented semiconductor wafer, preferably, a plurality of vertically oriented wafers supported in a wafer holding cassette the movable member being movable such that upon moving the movable member a contact surface of the movable member contacts the semiconductor wafers at a semiconductor wafer edge to project the semiconductor wafers in an upward direction with respect to the wafer cassette the semiconductor wafers being supported at least in part by the movable member.

It will be appreciated that the moveable member may be moved by any motive force including for example, manual, mechanical and hydraulic.

For example, in one exemplary embodiment of the present invention, an elongated member (movable member) is disposed below the vertically oriented wafers supported by the wafer holding cassette and is periodically at least partially rotated to contact a portion of the wafer circumference whereby the wafers are raised upward from a resting position in the cassette.

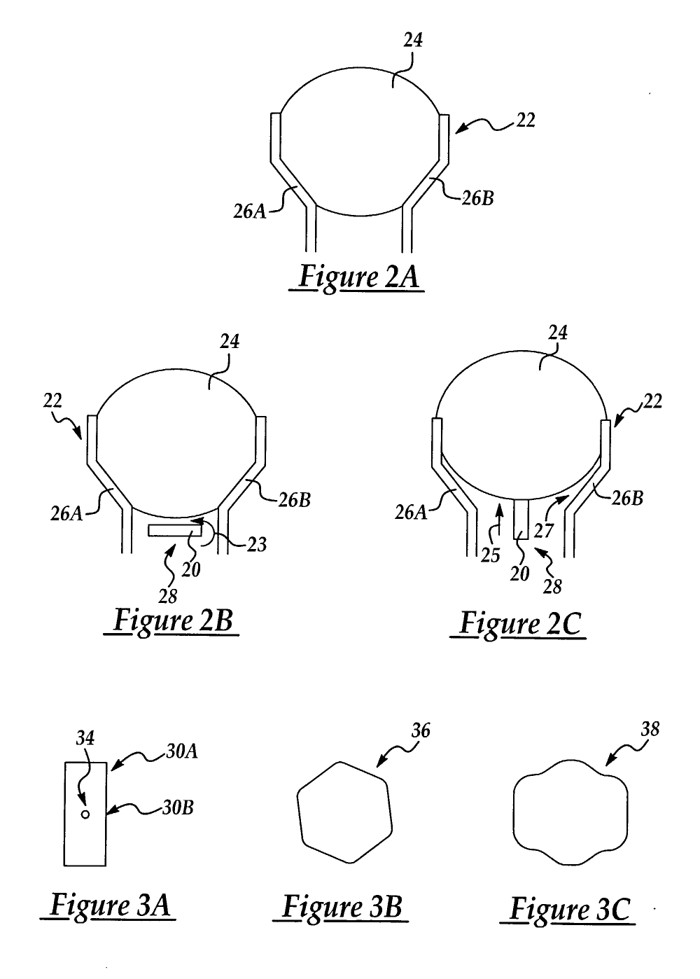

For example referring to FIG. 2A is shown a head on view of an exemplary cassette fixture (wafer cassette holder) 22 holding semiconductor wafers, e.g. 24. The cassette fixture typically includes angled lower portions 26A and 26B for supporting the semiconductor wafer 24. Preferably, the cassette fixture has an open bottom portion 28 to allow dislodged flakes of, for example, thick film photoresist to pass through during a stripping process. According to one embodiment of the present invention, an elongated member e.g., 20, elongated in a direction perpendicular to the major surface of the semiconductor wafer (along the length of the wafer cassette holder) is positioned below the semiconductor wafers e.g., 24 supported in the cassette fixture 22 such that upon at least partial rotation of the elongated member 20 as indicated by rotational arrow 23, the semiconductor wafers, e.g., 24 are projected in an upward direction indicated by directional arrow 25 with respect to the cassette fixture as shown in FIG. 2B. Preferably, the semiconductor wafer is at least projected upward to an extent that the wafer is no longer supported by angled lower portions 26A and 26B of the wafer cassette holder leaving a space e.g. 27 between at least portion of the angled lower portions 26A and 26B and the semiconductor wafers e.g., 24. Preferably, the semiconductor wafer is projected upward so that the wafer is clear of the angled lower portions 26A and 26B.

In order for the elongated member to raise the semiconductor wafer upon rotation, the peripheral portion of the elongated member is shaped such that a radial distance from the axis of rotation is variable around a radial periphery 30B (radial circumference) of the elongated member 30A. For example, referring to FIG. 3A showing across section of the elongated member 30A viewed along the axis of rotation of the elongated member 30A. The peripheral portion (radial periphery) 30B may be any shape having a variable radial distance from an axis of rotation e.g., centrally located as 34, to the peripheral portion 30B such that upon rotation of the elongated member 30A around its rotational axis e.g., 34, at least a portion of the periphery (peripheral portion) 30B contacts an edge of a semiconductor wafer as shown in FIG. 2B. For example, preferably the elongated member periphery viewed in cross section along a rotation axis is one of a rectangular shape 30A (FIG. 3A), a polygonal shape 36 (FIG. 3B), or a wave shape 38 (FIG. 3C).

Referring again to FIG. 2A, preferably, the elongated member is positioned below the semiconductor wafers, e.g., 24 within an open bottom portion 28. The wafers may optionally be positioned in contact with a peripheral portion of the elongated member while the wafers are in the rest or lowered positioned. In addition, the elongated member may optional be equipped with slots (not shown) radially positioned around the elongated member periphery surface for guiding the semiconductor wafer when raised or lowered.

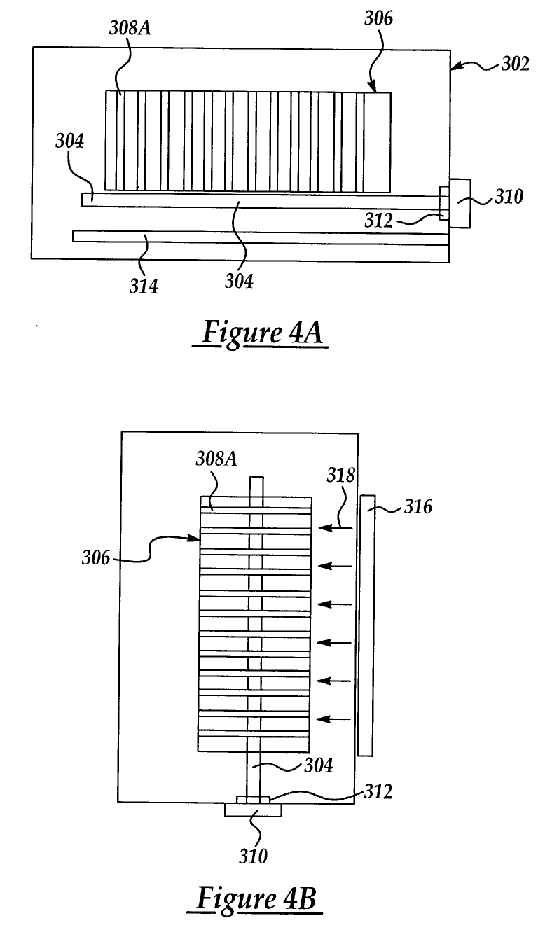

Referring to FIG. 4A, showing a side view of an exemplary embodiment of the stripping system according to one embodiment of the present invention, in exemplary operation, the elongated rotational member 304 is positioned in the lower portion of the stripping bath container 302 so that an axial portion of the elongated rotational member (elongated member) 304 is below and parallel to the length of the cassette 306 holding semiconductor wafers e.g., 308A. The elongated rotational member is preferably positioned so that upon at least upon partial rotation, at least a portion of the periphery of the elongated rotational member makes contact during a portion of the rotation with the wafer edge to raise and lower the wafer. For example, the elongated rotational member is preferably coupled to variable speed reversible motor 310 outside the stripping bath container 302 through a conventional sealing means 312 within the container to seal against stripping solution. In another exemplary embodiment the stripping bath may be optionally equipped with a source of agitation, for example, ultrasound such as a megasonic source oriented parallel to the wafer process surface, or a bubble generator positioned in a lower portion of the stripping bath container, both of which are well known in the art. The agitation source is applied simultaneously with the upward and downward movement of the semiconductors to aid in dislodging the photoresist flakes. For example, shown in FIG. 4A is a bubble generator 314 positioned below the elongated rotational member from which gas bubbles are generated in an upward direction supplied by a gas source (not shown) outside the stripping bath container. Preferably, a conventional megasonic ultrasound source is used and includes a transducer producing sonic energy at a frequency of about 850 to 900 kHz. As shown in FIG. 4B showing a top views of the stripping system, the sonic energy is preferably directed parallel to the semiconductor wafer surfaces as indicated by directional arrows e.g., 318 from a megasonic source 316 mounted at an outer portion of the stripping bath container.

Referring again to FIG. 2A, in operation, the elongated member (elongated rotational member) 20 is periodically rotated to raise and lower the semiconductor wafers, e.g., 24 in the cassette holder 22 during the stripping action of the stripping bath. Upon rotation of the elongated member 20, the semiconductor wafer may coincidentally be rotated in the cassette holder, for example, in a rotational direction oppositely oriented with respect to the rotational direction of the elongated member. During the rotation, photoresist flakes are dislodged from the semiconductor wafer, and accumulated photoresist residue is dislodged from the cassette holder 22 including the angled lower portions 26A and 26B. The elongated member 20 may be rotated at varying rates depending on the extent of photoresist flake accumulation. It will be appreciated that the rate of photoresist accumulation will depend in part on the temperature and chemical makeup of the stripper solution. For example, the elongated member may be rotated from about 5 to about 15 rpm.

In one embodiment, the elongated member is preferably powered by a reversible variable speed motor and where the elongated rotational member may be rotatably moved in a clockwise or counter-clockwise direction around the rotational axis of the elongated rotational member and may optionally periodically change directions. Preferably the elongated member is formed of a plastic or other material that is inert to the stripping solution and will not damage the semiconductor wafer edge, for example, polyethylene or PTFE.

The preferred embodiments, aspects, and features of the invention having been described, it will be apparent to those skilled in the art that numerous variations, modifications, and substitutions may be made without departing from the spirit of the invention as disclosed and further claimed below.

What is claimed is:

1. A method for avoiding particulate contamination of a semiconductor wafer in a stripping bath comprising the steps of:
providing at least one semiconductor wafer vertically oriented in a wafer containing fixture;
providing a solution bath for removing particulate material from a semiconductor wafer surface;
immersing the wafer containing fixture in the solution bath positioned over a movable member having a contact surface such that upon moving the movable member in a vertical direction the contact surface contacts a portion of the edge of the at least one semiconductor; and
moving the movable member such that the at least one semiconductor wafer is projected upward from a resting position in the wafer containing fixture.

2. The method of claim 1, wherein the movable member is rotatable about an axis of rotation such that upon at least partial rotation at least a portion of the contact surface including a periphery makes contact with the at least one semiconductor wafer edge.

3. The method of claim 1, wherein the step of moving further comprises periodically moving the movable member such that the semiconductor wafer is periodically projected upward from the resting position.

4. The method of claim 2, wherein the periphery is at a variable radial distance with respect to the axis of rotation including an axial direction of the movable member.

5. The method of claim 2, wherein the step of moving further comprises rotating the movable member causing the semiconductor wafer to be projected upward and downward in accordance with at least a portion of the periphery having a variable radial distance with respect to the axis of rotation.

6. The method of claim 4, wherein the semiconductor edge contacts a radially formed slotted area in the contact surface to guide the semiconductor wafer.

7. The method of claim 1, wherein the wafer containing fixture contains a plurality of semiconductor wafers.

8. The method of claim 7, wherein the movable member is elongated along the length of the wafer containing fixture to contact each of the plurality of semiconductor wafers.

9. The method of claim 1, wherein the solution bath is a stripping bath for removing a thick film photoresist.

10. The method of claim 1, wherein the semiconductor wafer includes a thick film photoresist to be at least partially removed according to a solder bump forming procedure.

11. The method of claim 1, further comprising the step of simultaneously agitating the solution bath.

12. The method of claim 1, wherein the step of moving further comprises rotating the rotatable member at a rate of about 5 to about 15 rpm.

12. A stripping system for avoiding particulate contamination of a semiconductor wafer in a stripping bath comprising:
a stripping solution container for holding a stripping solution and for containing a plurality of semiconductor wafers vertically oriented in a wafer cassette holder the stripping solution container including an elongated rotatable member positioned in the lower portion of the stripping solution container such that upon positioning the wafer cassette holder over at least an axial portion of the elongated rotatable member at least a radial portion of the elongated rotatable member periphery contacts the plurality of semiconductors at an edge at least upon rotation about an axial direction of the elongated rotatable member to project the plurality of semiconductors in an upward direction from a resting position in the wafer cassette holder.

13. The stripping system of claim 12, wherein the elongated rotatable member is axially rotatable about an angle of about 45 degrees to about 360 degrees.

14. The stripping system of claim 12, wherein the elongated rotatable member is continuously rotatable including a clockwise and counter-clockwise direction.

15. The stripping system of claim 12, wherein the elongated rotatable member is rotatably powered by a reversible variable speed motor.

16. The stripping system of claim 12, wherein the elongated rotatable member further comprises a radial periphery having a variable distance with respect to the axis of rotation of the rotatable member.

17. The stripping system of claim 16, wherein the radial periphery comprises a geometry including at least one of a rectangular, polygonal, and wave shape.

18. The stripping system of claim 12, wherein at least a portion of a radially peripheral surface of the elongated rotatable member includes a slotted area for contacting a semiconductor wafer edge during at least a portion of the rotation.

19. The stripping system of claim 12, further comprising an agitating source for agitating the stripping solution including at least one of a megasonic and gas bubble source.

20. The stripping system of claim 12 wherein the elongated rotatable member is adjustably rotatable at a rate of about 5 to about 15 rpm.
